(19) United States
(12) Patent Application Publication
(10) Pub. No.: US 2026/0012158 A1
(43) Pub. Date: Jan. 8, 2026

(54) Feedforward Notch Filter Circuitry

(71) Applicant: Apple Inc., Cupertino, CA (US)

(72) Inventor: Milad Darvishi, San Diego, CA (US)

(21) Appl. No.: 19/059,912

(22) Filed: Feb. 21, 2025

Related U.S. Application Data
(60) Provisional application No. 63/667,249, filed on Jul. 3, 2024.

(51) Int. Cl. H03H 11/04

(52) U.S. Cl. CPC H03H 11/0422; H03H 2011/0488

(57) ABSTRACT

Circuitry is provided that includes a transconductance circuit and a notch filter coupled along a feedforward path between an input of the transconductance circuit and an output of the transconductance circuit. The notch filter can include a first series resistor having a first terminal coupled to the input of the transconductance circuit and having a second terminal and can further include a second series resistor having a first terminal coupled to the second terminal of the first series resistor and having a second terminal coupled to the output of transconductance circuit. The notch filter can have a notch frequency that is a function of a resistance of the first and second series resistors. The notch frequency can be adjusted.

This application claims the benefit of U.S. Provisional Patent Application No. 63/667,249, filed Jul. 3, 2024, which is hereby incorporated by reference herein in its entirety.

### FIELD

This disclosure relates generally to electronic circuits, including electronic circuits with filters.

### BACKGROUND

Electronic circuits can include filters such as low-pass filters. A low-pass filter is a circuit that passes signals having frequencies lower than a certain cutoff frequency while attenuating or rejecting signals having frequencies greater than the cutoff frequency. An analog low-pass filter can be implemented as a RC filter that includes a series resistor (R) and a shunt capacitor (C).

An RC low-pass filter may be insufficient in certain applications. Sometimes, a low-pass filter can be coupled to a notch filter to further attenuate spurious emissions. It can be challenging to design a notch filter. It is within such context that the embodiments herein arise.

### SUMMARY

An aspect of the disclosure provides circuitry that includes a transconductance circuit and a notch filter coupled along a feedforward path between an input of the transconductance circuit and an output of the transconductance circuit. The notch filter can include a first series resistor having a first terminal coupled to the input of the transconductance circuit and having a second terminal and a second series resistor having a first terminal coupled to the second terminal of the first series resistor and having a second terminal coupled to the output of transconductance circuit, where the notch filter can have a notch frequency based on a resistance of the first and second series resistors. The notch filter can include a first capacitor having a first terminal coupled to a node disposed between the first and second series resistors and having a second terminal coupled to a ground power supply line, a second capacitor having a first terminal coupled to the input terminal of the transconductance circuit and having a second terminal coupled to the first terminal of the first series resistor, and a third capacitor having a first terminal coupled to the second terminal of the second series resistor and having a second terminal coupled to the output of the transconductance circuit. The transconductance circuit can have a transconductance value based on the resistance of the first and second series resistors.

An aspect of the disclosure provides a notch filter that includes a first series resistor having a first terminal coupled to an input of a transconductance circuit, a second series resistor having a first terminal coupled to a second terminal of the first series resistor and having a second terminal coupled to an output of the transconductance circuit, and a first capacitor having a first terminal directly coupled to the second terminal of the first series resistor and having a second terminal coupled to a power supply line. The notch filter can further include a second capacitor having a first terminal coupled to the input terminal of the transconductance circuit and having a second terminal coupled to the first terminal of the first series resistor and a third capacitor having a first terminal coupled to the second terminal of the second series resistor and having a second terminal coupled to the output of the transconductance circuit. The first and second series resistors can have the same fixed resistance value. The first, second, and third capacitors can have the same adjustable capacitance value. The transconductance circuit can have a transconductance value based on the fixed resistance value of the first and second series resistors.

An aspect of the disclosure provides a notch filter that includes a first series resistor having a first terminal coupled to an input of a transconductance circuit, a second series resistor having a first terminal coupled to a second terminal of the first series resistor and having a second terminal coupled to an output of the transconductance circuit, a first shunt capacitor having a first terminal coupled to the second terminal of the first series resistor and having a second terminal coupled to a power supply line, and a second shunt capacitor having a first terminal coupled to the first terminal of the second series resistor and having a second terminal coupled to the power supply line. The notch filter can further include a series capacitor having a first terminal coupled to the first terminal of the first shunt capacitor and having a second terminal coupled to the first terminal of the second shunt capacitor.

### BRIEF DESCRIPTION OF THE DRAWINGS

FIG. 1 is a diagram of a transconductance circuit coupled to an illustrative notch filter in accordance with some embodiments.

FIG. 2 is a diagram showing an illustrative notch filter having one shunt path in accordance with some embodiments.

FIG. 3 is a diagram showing an illustrative notch filter having two shunt paths in accordance with some embodiments.

FIG. 4 is a plot of an illustrative notch filter response in accordance with some embodiments.

FIG. 5 is a diagram showing noise contribution from feedforward resistors as a function of frequency in accordance with some embodiments.

FIG. 6 is a block diagram of illustrative wireless circuitry that can be provided with a notch filter in accordance with some embodiments.

FIG. 7 is a circuit diagram showing illustrative wireless circuitry having a feedforward notch filter coupled between a data converter and a mixer in accordance with some embodiments.

### DETAILED DESCRIPTION

Electronic circuits can include filter circuitry. Filter circuitry such as notch filter circuitry can be configured to reject or attenuate signals at a particular notch frequency. The notch filter circuitry can include passive components coupled between an input and an output of an associated transconductance circuit via a feedforward path. The feedforward path can include multiple series resistors that are coupled to one or more capacitive shunt paths. The one or more capacitive shunt paths can include at least one capacitor with an adjustable capacitance for tuning the notch frequency.

Notch filter circuitry configured in this way is technically advantageous and beneficial to provide a tunable notch frequency without introducing in-band noise. In some embodiments, the notch filter circuitry can be incorporated as part of wireless communications circuitry within an electronic device. For example, the notch filter circuitry can be included as part of a transmit signal path of the wireless communications circuitry. In general, the low-pass filter circuitry can be included as part of a transmit signal path, a receive signal path, or other data paths on one or more integrated circuits.

An electronic device that includes the notch filter circuitry can be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

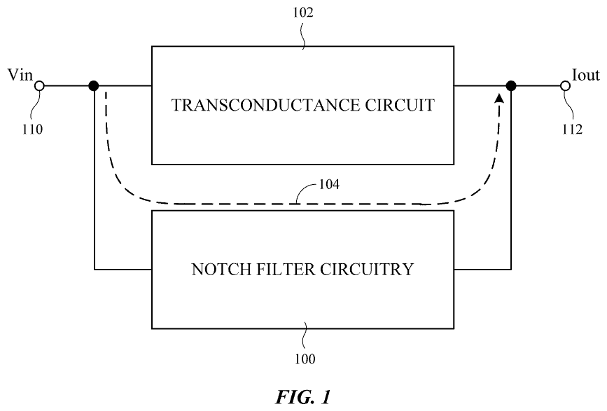

FIG. 1 is a diagram of illustrative notch filter circuitry such as notch filter circuitry 100 coupled to a transconductance circuit 102. As shown in FIG. 1, transconductance circuit 102 can have a input terminal (port) 110 configured to receive an input signal (voltage) Vin and an output terminal (port) 112 on which output current Iout can be produced. Transconductance circuit 102 can refer to and be defined herein as an electronic circuit configured to convert an input voltage such as Vin into a corresponding output current such as Iout. As an example, transconductance circuit 102 can be a transistor such as a metal-oxide-semiconductor field-effect transistor (MOSFET), bipolar junction transistor (BJT), insulated-gate bipolar transistor (IGBT), junction field-effect transistor (JFET), tunnel field-effect transistor (TFET), fin field-effect transistor (FinFET), silicon-on-insulator (SOI) transistor, carbon nanotube transistor, nanowire transistor, a combination of these transistors, and/or other types of transistors. As another example, transconductance circuit 102 can be an operational transconductance amplifier (OTA). If desired, other types of transconductance circuit 102 can be used in conjunction with notch filter circuitry 100, described below. Transconductance circuit 102 can exhibit a transconductance gₘ, an operating parameter defined as the ratio of a change in output current Iout to a change in input voltage Vin (i.e., gₘ=δIout/δVin).

In accordance with an embodiment, notch filter circuitry 100 can be coupled between input terminal 110 and output terminal 112 of transconductance circuit 102. Notch filter circuitry 100 is disposed in a feedforward path 104 between input terminal 110 and output terminal 112. Notch filter circuitry 110 is thus sometimes referred to herein as a feedforward based notch filter or a feedforward notch filter. Notch filter 100 can refer to and be defined herein as a filter configured to attenuate signals in a specific range of frequencies while passing signals having frequencies outside that range. The range of frequencies or the frequency at which maximum attenuation is achieved by notch filter 100 can be referred to as a notch frequency (range), a center frequency (range), a rejection frequency (range), a null frequency (range), a stopband frequency (range), or an attenuation frequency (range). Notch filter 100 can thus be employed to attenuate or reject unwanted spurious signals at a particular frequency or range of frequencies.

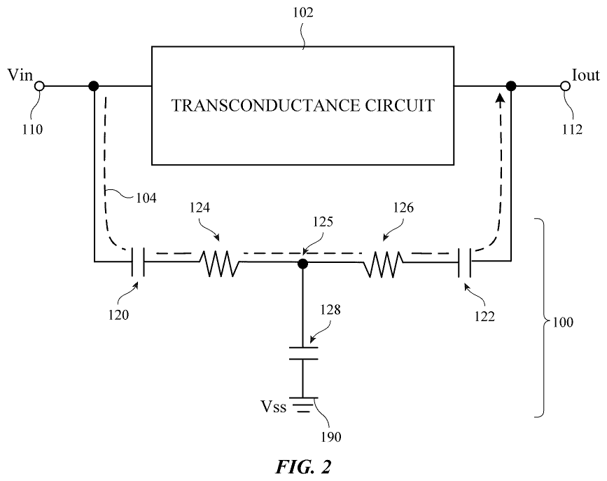

FIG. 2 is a circuit diagram showing an implementation of notch filter circuitry 100. As shown in FIG. 2, notch filter circuitry 100 can include one or more resistors such as resistors 124 and 126 and one or more capacitors such as capacitors 120, 122, and 128. Capacitor 120 may have a first terminal coupled to input terminal 110 of transconductance circuit 102 and a second terminal coupled to resistor 124. Resistor 124 may have a first terminal coupled to the second terminal of capacitor 120 and a second terminal coupled to node 125. Resistor 126 may have a first terminal coupled to node 125 and a second terminal coupled to capacitor 122. Capacitor 122 may have a first terminal coupled to the second terminal of resistor 126 and a second terminal coupled to output terminal 112 of transconductance circuit 102. Resistors 124 and 126 disposed along the dotted feedforward path 104 can be referred to as series resistors or feedforward resistors. Capacitors 120 and 122 disposed along the feedforward path can be referred to as series capacitors or feedforward capacitors. Capacitor 128 can have a first terminal coupled to node 125 and a second terminal coupled to a power supply line 190 (e.g., a ground power supply terminal on which ground power supply voltage Vss is provided). Capacitor 128 is sometimes referred to as a shunt capacitor. Notch filter circuitry 100 of FIG. 2 can thus include one shunt path coupled along the feedforward path.

Notch filter circuitry 100 can have a notch frequency calculated as follows:

$${ω}_{notch} = \frac{\sqrt{3}}{RC} \qquad ( 1 )$$

where R represents the resistance value of each of resistors 124 and 126, and where C represents the capacitance value of each of capacitors 120 and 122. In other words, series resistors 124 and 126 should have equal (fixed) resistance values, whereas series capacitors 120 and 122 should have equal capacitance values. Notch filter circuitry 100 configured using the arrangement of FIG. 2 can thus be considered to exhibit a symmetrical or mirrored structure. Moreover, the transconductance gₘ of transconductance circuit 102 should also be a function of resistance R. In particular, the transconductance of circuit 102 should be configured as follows:

$${g}_{m} = \frac{1}{4 R} \qquad ( 2 )$$

In other words, resistance R is also a function of transconductance gₘ. Since resistance R is a function of transconductance gₘ, capacitance C is thus freely adjustable to tune the notch frequency of filter 100. Capacitors 120, 122, and 128 can thus be adjustable capacitors (e.g., switchable capacitive banks, variable capacitors, or other types of tunable capacitive circuits). For instance, the notch frequency can be increased by reducing capacitance C or can be decreased by increasing capacitance C.

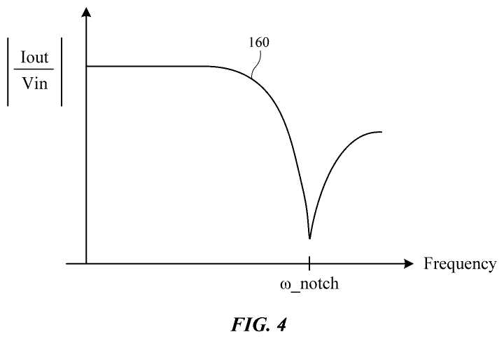

Notch filter circuitry 100 configured in this way can thus exhibit a notch filter response as shown in FIG. 4. FIG. 4 plots the magnitude of transconductance (e.g., Iout/Vin) across the input and output of filter 100 as a function of frequency ω (in radians). As shown in FIG. 4, notch frequency response 160 can exhibit a notch frequency ω_{notch} that can be calculated in accordance with equation (1).

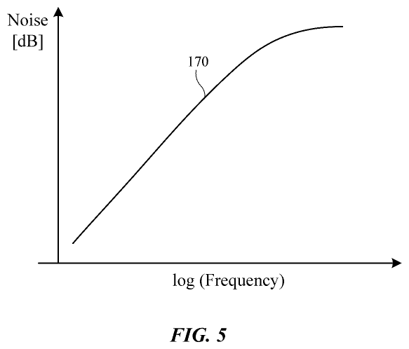

FIG. 5 is a diagram showing noise contribution from series (feedforward) resistors 124 and 126 as a function of frequency in accordance with some embodiments. In particular, profile 170 plots an amount of noise produced from resistors 124 and 126 as a function of frequency (in logarithmic scale). As shown by curve 170 in FIG. 5, the in-band noise contribution at low (er) frequencies is relatively low or attenuated, so the addition of resistors 124 and 126 in the feedforward path introduces minimal noise to the overall circuitry. Thus, notch filter circuitry 100 of the type shown in FIG. 2 is technically advantageous and beneficial to provide a tunable (adjustable) notch frequency in conjunction with an associated transconductance circuit with minimal in-band noise impact.

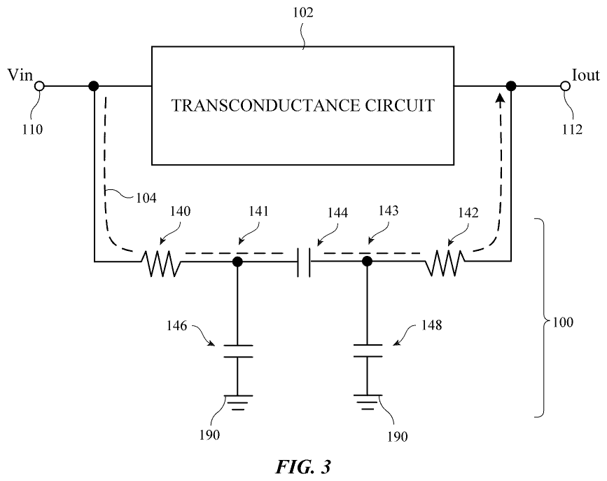

The embodiment of notch filter circuitry 100 shown in FIG. 2 having a single shunt path (e.g., shunt capacitor 128) is exemplary. FIG. 3 is a diagram illustrating another embodiment of notch filter circuitry 100 having multiple shunt paths in accordance with some embodiments. As shown in FIG. 3, notch filter circuitry 100 can include one or more resistors such as resistors 140 and 142 and one or more capacitors such as capacitors 144, 146, and 148. Resistor 140 may have a first terminal coupled to input terminal 110 of transconductance circuit 102 and a second terminal coupled to node 141. Capacitor 144 may have a first terminal coupled to node 141 and a second terminal coupled to node 143. Resistor 142 may have a first terminal coupled to node 143 and a second terminal coupled to output terminal 112 of transconductance circuit 102.

Resistors 140 and 142 disposed along the dotted feedforward path 104 can be referred to as series resistors or feedforward resistors. Capacitor 144 disposed along the feedforward path can be referred to as a series capacitor or a feedforward capacitor. Capacitor 146 may have a first terminal coupled to node 141 (e.g., a node disposed between resistor 140 and capacitor 144) and a second terminal coupled to ground power supply line 190. Capacitor 148 may have a first terminal coupled to node 143 (e.g., a node disposed between resistor 142 and capacitor 144) and a second terminal coupled to ground power supply line 190. Capacitor 146 is sometimes referred to as a first shunt capacitor that is part of a first shunt path. Capacitor 148 is sometimes referred to as a second shunt capacitor that is part of a second shunt path. Notch filter circuitry 100 of FIG. 3 can thus include two shunt paths coupled along the feedforward path 104.

Notch filter circuitry 100 can have a notch frequency that can be calculated in accordance with equation (1) shown above, where R represents the resistance value of each of resistors 140 and 142, and where C represents three times the capacitance value of each of capacitors 144, 146, and 148. In other words, feedforward/series resistors 140 and 142 should have equal resistance (fixed) values, whereas capacitors 144, 146, and 148 should have equal capacitance values. Notch filter circuitry 100 configured in the arrangement of FIG. 3 can thus be considered to exhibit a symmetrical or mirrored structure.

Moreover, the transconductance gₘ of transconductance circuit 102 in FIG. 3 should also be a function of resistance R. In particular, the transconductance of circuit 102 should be configured in accordance with equation (2) shown above. In other words, resistance R is also a function of transconductance gₘ. Since resistance R is a function of transconductance gₘ, capacitance C is thus freely adjustable to tune the notch frequency of filter 100. Capacitors 144, 146, and 148 can thus be adjustable capacitors (e.g., switchable capacitive banks, variable capacitors, or other types of tunable capacitive circuits). For instance, the notch frequency can be increased by reducing capacitance C or can be decreased by increasing capacitance C.

Notch filter circuitry 100 configured in this way can thus exhibit a notch filter response as shown in FIG. 4. FIG. 4 plots the magnitude of transconductance (e.g., Iout/Vin) across the input and output of filter 100 as a function of frequency ω (in radians). As shown in FIG. 4, notch frequency response 160 can exhibit a notch frequency ω_{notch} that can be calculated in accordance with equation (1). FIG. 5 is a diagram showing noise contribution from series (feedforward) resistors 140 and 142 as a function of frequency in accordance with some embodiments. In particular, profile 170 plots an amount of noise produced from resistors 140 and 142 as a function of frequency (in logarithmic scale). As shown by curve 170 in FIG. 5, the in-band noise contribution at low (er) frequencies is relatively low or attenuated, so the use of series resistors 140 and 142 in the feedforward path introduces minimal noise to the overall circuitry. Thus, notch filter circuitry 100 of the type shown in FIG. 3 is technically advantageous and beneficial to provide a tunable (adjustable) notch frequency in conjunction with an associated transconductance circuit with minimal in-band noise impact.

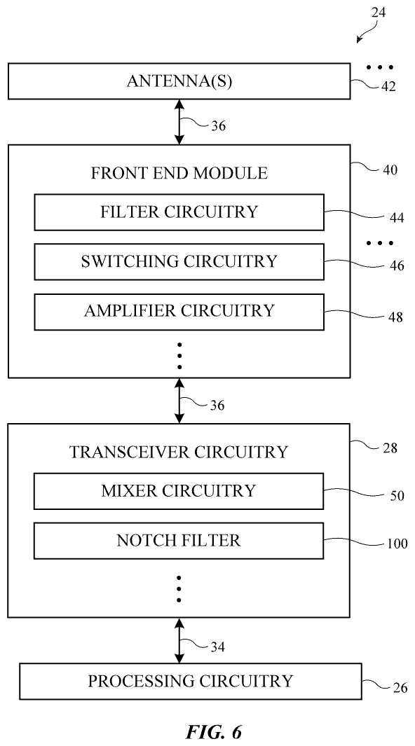

Filter circuitry 100 of the type described in connection with FIGS. 1-5 can be included as part of wireless circuitry in accordance with some embodiments. FIG. 6 is a block diagram of illustrative wireless circuitry 24 that can be provided with filter circuitry 100. Wireless circuitry 24 is sometimes referred to as wireless communications circuitry. As shown in FIG. 6, wireless circuitry 24 may include processing circuitry such as processing circuitry 26 (e.g., one or more processors), radio-frequency (RF) transceiver circuitry such as radio-frequency transceiver 28, radio-frequency front end circuitry such as radio-frequency front end module (FEM) 40, and antenna(s) 42. Processing circuitry 26 may include one or more baseband processor, application processor, digital signal processor, microcontroller, microprocessor, central processing unit (CPU), programmable device, a combination of these circuits, and/or other types of processing units. Processing circuitry 26 may be configured to generated digital (baseband) signals.

In the example of FIG. 6, wireless circuitry 24 is illustrated as including only a single processing unit 26, a single transceiver 28, a single front end module 40, and a single antenna 42 for the sake of clarity. In general, wireless circuitry 24 may include any desired number of processing units 26, any desired number of transceivers 28, any desired number of front end modules 40, and any desired number of antennas 42. Each processing unit 26 may be coupled to one or more transceivers 28 over respective baseband paths 34. Each transceiver 28 may include a transmitter circuit configured to output uplink signals to antenna 42, may include a receiver circuit configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module.

Processing circuitry 26 may be coupled to transceiver 28 over baseband path 34. Transceiver 28 may be coupled to antenna 42 via radio-frequency transmission line path 36. Radio-frequency front end module 40 may be disposed on radio-frequency transmission line path 36 between transceiver 28 and antenna 42. Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within an electronic device. Transmission lines in the electronic device may include coaxial cables, microstrip transmission lines, stripline transmission lines, edge-coupled microstrip transmission lines, edge-coupled stripline transmission lines, transmission lines formed from combinations of transmission lines of these types, etc. Transmission lines such as transmission lines in radio-frequency transmission line path 36 may be integrated into rigid and/or flexible printed circuit boards.

Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

Front end module (FEM) 40 may include radio-frequency front end circuitry that operates on the radio-frequency signals conveyed (transmitted and/or received) over radio-frequency transmission line path 36. Front end module 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifiers and one or more low-noise amplifiers), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip or on separate integrated circuit chips.

Filter circuitry 44, switching circuitry 46, amplifier circuitry 48, and other circuitry may be disposed on radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of an electronic device, a rigid printed circuit board, or flexible printed circuit that is not a part of front end module 40. Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHZ), a 5 GHz WLAN band (e.g., from 5180 to 5825 MHZ), a Wi-Fi® 6E band (e.g., from 5925-7125 MHZ), and/or other Wi-Fi® bands (e.g., from 1875-5160 MHZ), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio (NR) Frequency Range 1 (FR1) bands below 10 GHz, 5G New Radio Frequency Range 2 (FR2) bands between 20 and 60 GHz, etc.), 6G bands between 100-1000 GHz (e.g., sub-THz. TH2, or THF bands), etc.), other centimeter or millimeter wave frequency bands between 10-300 GHz (e.g., a short range wireless data transfer band that supports in-band full duplex communications such as a band between around 57 GHz and 64 GHz), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

In performing wireless transmission, processing circuitry 26 may provide baseband signals to transceiver 28 over baseband path 34. Transceiver 28 may further include circuitry for converting the baseband signals received from processing circuitry 26 into corresponding radio-frequency signals. For example, transceiver circuitry 28 may include mixer circuitry 50 for up-converting (or modulating) the baseband signals to intermediate frequencies or radio frequencies prior to transmission over antenna 42. Transceiver circuitry 28 may also include digital-to-analog converter (DAC) and/or analog-to-digital converter (ADC) circuitry for converting signals between digital and analog domains. Transceiver 28 may include a transmitter component to transmit the radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from external wireless equipment. The received radio-frequency signals may be conveyed to transceiver 28 via radio-frequency transmission line path 36 and front end module 40. Transceiver 28 may include circuitry for converting the received radio-frequency signals into corresponding baseband signals. For example, transceiver 28 may use mixer circuitry 50 for down-converting (or demodulating) the received radio-frequency signals to intermediate frequencies or baseband frequencies prior to conveying the received signals to processing circuitry 26 over baseband path 34.

Transceiver 28 may further include a filter circuit such as notch filter circuitry 100 of the type described in connection with FIGS. 1-5. The example of FIG. 6 in which filter circuitry 100 is shown as being part of transceiver circuitry 28 is merely illustrative. If desired, other parts of wireless communications circuitry 24 can include low-pass filter circuitry 100. As an example not mutually exclusive with the other embodiments, one or more instances of filter circuitry 100 can be included as part of processing circuitry 26. As another example not mutually exclusive with the other embodiments, filter circuitry 100 can be included as part of front end module 40. Filter circuitry 100 need not be included as part of wireless circuitry 24. In general, filter circuitry 100 can be included as part of any electronic circuit that requires notch filtering.

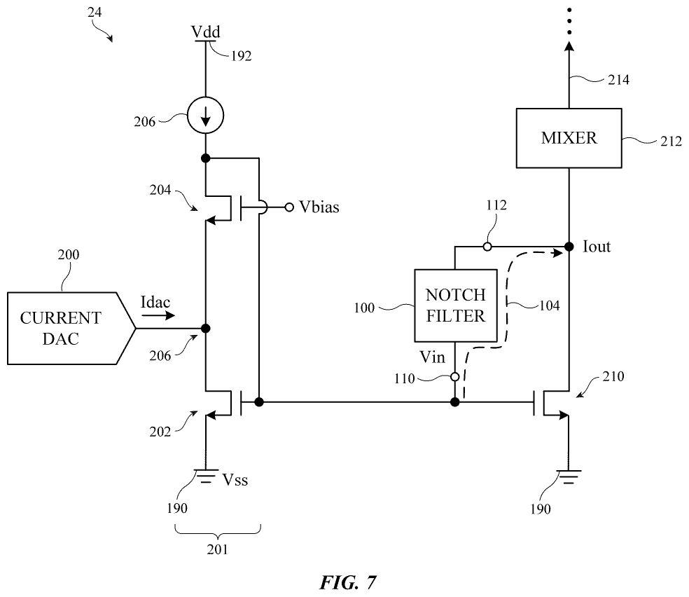

FIG. 7 is a circuit diagram showing how wireless circuitry 24 can include filter circuitry 100 coupled between a data converter and a mixer in accordance with some embodiments. As shown in FIG. 7, wireless circuitry 24 can include a data converter such as a digital-to-analog converter (DAC) 200, a current mirror circuit 201, a transistor such as transistor 210, and a mixer 212. Digital-to-analog converter 200 can be configured to output a current signal Idac and can thus sometimes referred to as a current DAC. Current DAC 200 can output current signal Idac to current mirror 201.

Current mirror 201 can include transistor 202, transistor 204, and current source 206 coupled together in series between ground (Vss) line 190 and positive power supply (Vdd) line 192 (e.g., a positive power supply terminal on which positive power supply voltage Vdd is provided). In particular, current source 206 may be coupled between Vdd line 192 and transistor 204. Transistor 204 (e.g., an NMOS transistor) can have a drain terminal coupled to current source 206, a gate terminal configured to receive a bias voltage Vbias, and a source terminal coupled to node 206. Node 206 may be coupled to the output of current DAC 200. Transistor 202 (e.g., an NMOS transistor) can have a drain terminal coupled to node 206, a source terminal coupled to Vss line 190, and a gate terminal coupled (shorted) to the drain terminal of transistor 204.

Notch filter circuitry 100 may have its input terminal 110 coupled to the gate terminal of transistor 202 within current mirror 201 and its output terminal 112 coupled to the drain terminal of transistor 210. In particular, transistor 210 (e.g., an NMOS transistor) can have a gate terminal coupled to filter circuitry 100, a source terminal coupled to ground line 190, and a drain terminal coupled to mixer 212. Mixer 212 may represent a mixer component within mixer circuitry 50 of FIG. 6. Mixer 212 can be coupled to other downstream circuitry as indicated by connection 214. The terms “source” and “drain” are sometimes used interchangeably when referring to current-conducting terminals of a metal-oxide-semiconductor transistor. The source and drain terminals are therefore sometimes referred to as “source-drain” terminals (e.g., a transistor has a gate terminal, a first source-drain terminal, and a second source-drain terminal).

The example of FIG. 7 in which notch filter circuitry 100 is coupled to an n-type transistor 21—between a current mirror 201 and a mixer 212 is illustrative. In other embodiments, filter circuitry 100 can be coupled across gate and source-drain terminals of a p-type transistor, across the input and output terminals of an operational transconductance amplifier (OTA), or across other types of transconductance circuits. In general, filter circuitry 100 can additionally or alternatively be incorporated into other parts of wireless circuitry 24. Filter circuitry 100 need not be included as part of wireless circuitry 24. In general, filter circuitry 100 can be included as part of any electronic circuit that requires notch filtering.

The foregoing is merely illustrative and various modifications can be made to the described embodiments. The foregoing embodiments may be implemented individually or in any combination.

What is claimed is:

1. Circuitry comprising:
a transconductance circuit; and
a notch filter coupled along a feedforward path between an input of the transconductance circuit and an output of the transconductance circuit, wherein the notch filter comprises:
a first series resistor having a first terminal coupled to the input of the transconductance circuit and having a second terminal; and
a second series resistor having a first terminal coupled to the second terminal of the first series resistor and having a second terminal coupled to the output of transconductance circuit, wherein the notch filter has a notch frequency based on a resistance of the first and second series resistors.

2. The circuitry of claim 1, wherein the notch filter further comprises:
a first capacitor having a first terminal coupled to a node disposed between the first and second series resistors and having a second terminal coupled to a ground power supply line.

3. The circuitry of claim 2, wherein the notch filter further comprises:
a second capacitor having a first terminal coupled to the input terminal of the transconductance circuit and having a second terminal coupled to the first terminal of the first series resistor.

4. The circuitry of claim 3, wherein the notch filter further comprises:
a third capacitor having a first terminal coupled to the second terminal of the second series resistor and having a second terminal coupled to the output of the transconductance circuit.

5. The circuitry of claim 4, wherein the first capacitor has a first capacitance, wherein the second capacitor has a second capacitance equal to the first capacitance, wherein the third capacitor has a third capacitance equal to the first capacitance, and wherein the notch frequency is based on the first capacitance.

6. The circuitry of claim 5, wherein the first capacitance, the second capacitance, and the third capacitance have equal adjustable values.

7. The circuitry of claim 1, wherein the transconductance circuit has a transconductance value based on the resistance of the first and second series resistors.

8. The circuitry of claim 1, wherein the notch filter further comprises:
a first capacitor having a first terminal coupled to the second terminal of the first series resistor and having a second terminal coupled to the first terminal of the second series resistor.

9. The circuitry of claim 8, wherein the notch filter further comprises:
a second capacitor having a first terminal coupled to a node disposed between the first series resistor and the first capacitor and having a second terminal coupled to a ground power supply line.

10. The circuitry of claim 9, wherein the notch filter further comprises:
a third capacitor having a first terminal coupled to a node disposed between the first capacitor and the second series resistor and having a second terminal coupled to the ground power supply line.

11. The circuitry of claim 10, wherein the first capacitor has a first capacitance, wherein the second capacitor has a second capacitance equal to the first capacitance, wherein the third capacitor has a third capacitance equal to the first capacitance, and wherein the notch frequency is based on the first capacitance.

12. The circuitry of claim 11, wherein the first capacitance, the second capacitance, and the third capacitance have equal adjustable values.

13. The circuitry of claim 1, wherein the transconductance circuit comprises a transistor having a gate terminal coupled to the input and having a source-drain terminal coupled to the output.

14. A notch filter comprising:
a first series resistor having a first terminal coupled to an input of a transconductance circuit;
a second series resistor having a first terminal coupled to a second terminal of the first series resistor and having a second terminal coupled to an output of the transconductance circuit; and
a first capacitor having a first terminal directly coupled to the second terminal of the first series resistor and having a second terminal coupled to a power supply line.

15. The notch filter of claim 14, further comprising:
a second capacitor having a first terminal coupled to the input terminal of the transconductance circuit and having a second terminal coupled to the first terminal of the first series resistor.

16. The circuitry of claim 15, wherein the notch filter further comprises:
a third capacitor having a first terminal coupled to the second terminal of the second series resistor and having a second terminal coupled to the output of the transconductance circuit.

17. The circuitry of claim 16, wherein:
the first series resistor has a fixed resistance value;
the second series resistance has the fixed resistance value;
the first capacitor has an adjustable capacitance value;
the second capacitor has the adjustable capacitance value;
the third capacitor has the adjustable capacitance value; and
the transconductance circuit has a transconductance value based on the fixed resistance value of the first and second series resistors.

18. A notch filter comprising:
a first series resistor having a first terminal coupled to an input of a transconductance circuit;
a second series resistor having a first terminal coupled to a second terminal of the first series resistor and having a second terminal coupled to an output of the transconductance circuit;
a first shunt capacitor having a first terminal coupled to the second terminal of the first series resistor and having a second terminal coupled to a power supply line; and
a second shunt capacitor having a first terminal coupled to the first terminal of the second series resistor and having a second terminal coupled to the power supply line.

19. The notch filter of claim 18, further comprising:
a series capacitor having a first terminal coupled to the first terminal of the first shunt capacitor and having a second terminal coupled to the first terminal of the second shunt capacitor.

20. The notch filter of claim 19, wherein:
the first series resistor has a fixed resistance value;
the second series resistance has the fixed resistance value;
the first shunt capacitor has an adjustable capacitance value;
the second shunt capacitor has the adjustable capacitance value;
the series capacitor has the adjustable capacitance value; and
the transconductance circuit has a transconductance value based on the fixed resistance value of the first and second series resistors.
